(19) United States
(12) Patent Application Publication
(10) Pub. No.: US 2009/0127603 A1
(43) Pub. Date: May 21, 2009

(54) SEMICONDUCTOR MEMORY DEVICE AND MANUFACTURING METHOD THEREOF

(76) Inventors: Koji Yamakawa, Tokyo (JP); Soichi Yamazaki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/265,492

(22) Filed: Nov. 5, 2008

(30) Foreign Application Priority Data
Nov. 9, 2007 (JP) 2007-292158

(51) Int. Cl. H01L 27/13; H01L 27/108

(52) U.S. Cl. 257/295; 438/3; 257/300; 257/E27.113; 257/E27.084

(57) ABSTRACT

A semiconductor memory device according to an embodiment comprises: a field-effect transistor formed on a substrate; an interlayer insulation film formed on the substrate on which the field-effect transistor is formed; and a ferroelectric capacitor including a lower electrode connected via a plug to one of source/drain regions of the field-effect transistor, and formed on the interlayer insulation film, a ferroelectric film having a perovskite crystal structure used as a basic structure, and an upper electrode, wherein a lattice matching region in which a lattice of the ferroelectric film is matched with a lattice of the lower electrode is formed in a range of a predetermined thickness of the ferroelectric film from the lower electrode.

### CROSS-REFERENCE TO RELATED APPLICATIONS

This application is based upon and claims the benefit of priority from the prior Japanese Patent Application No. 2007-292158, filed on Nov. 9, 2007; the entire contents of which are incorporated herein by reference.

### BACKGROUND OF THE INVENTION

1. Field of the Invention

The present invention relates to a semiconductor memory device and a manufacturing method thereof, and, more particularly to a semiconductor memory device including a capacitor using a ferroelectric film, and a manufacturing method thereof.

2. Description of the Related Art

Recently, development of ferroelectric random access memory (FeRAM) has been progressed for advantages of lower power consumption, high integration, high-speed operation, high endurance, nonvolatility, and random accessibility. As a configuration of the FeRAM, there has been known a type of FeRAM that includes one field-effect transistor (FET), and one ferroelectric capacitor having a ferroelectric film formed between a pair of electrodes, with a source region or a drain region of the FET electrically connected to one electrode of the ferroelectric capacitor.

Capacitor characteristics of the ferroelectric capacitor, such as a leak characteristic, a C-V characteristic, a polarization characteristic (such as a polarization amount, and a saturation characteristic), an imprint characteristic (a phenomenon that when a polarization is held in one direction, a polarization easily occurs in this direction), a fatigue characteristic (a degradation behavior of a polarization amount due to a polarization inversion), and a retention characteristic (a degradation behavior of a held polarization amount) are closely related to a material of an electrode and a crystal structure of the material. Therefore, the selection of the material is important. When a material having a crystal structure based on a perovskite structure such as Pb(Zrₓ, Ti₁₋ₓ)O₃(PZT), Bi₄Ti₃O₁₂(BIT), and SrBi₂Ta₂O₉(SBT), and having a residual polarization is used for a ferroelectric film, Ir, IrO₂, and Pt are used for a lower electrode, and a noble metal and a noble metal oxide such as Pt, Ir, IrO₂, Ru, RuO₂, SrRuO₃(SRO), LaNiO₃(LNO), and (La, Sr)CoO₃(LSCO), and a conductive composite oxide represented by a perovskite structure are used for an upper electrode.

Along the miniaturization of a capacitor cell area in recent years, as a FeRAM capacitor configuration, a capacitor-on-plug (COP) configuration has come to be employed that has a diffusion region of a field-effect transistor (FET), formed on a substrate, directly connected by a conductive plug to a lower electrode of a ferroelectric capacitor formed on an upper part of the diffusion region via an interlayer insulation film (for example, see Japanese Patent Application Laid-open No. 2003-258201). In this configuration, the capacitor is heated to 600° C. or above to crystallize the ferroelectric film at the time of forming the ferroelectric film on the lower electrode. Therefore, oxygen in the ferroelectric film is diffused to the conductive plug through the lower electrode. Consequently, a lower-electrode configuration including a lamination of a barrier film having oxygen barrier and a highly oxygen-resistant metal is formed on the conductive plug.

Further, miniaturization of the capacitor cell area has a problem in that process damage to the ferroelectric capacitor is increased. The process damage refers to inhibiting a polarization inversion of a ferroelectric substance by forming a fixed charge in the ferroelectric film, due to a trapping, inside the ferroelectric film or at an interface between the ferroelectric film and an electrode, of hydrogen and the like formed in a process such as a chemical vapor deposition (CVD) process to form a capacitor processing mask, a capacitor reactive-ion-etching (RIE) process, and an interlayer-insulation-film formation CVD process, or due to a oxygen defect in the ferroelectric film configuration, or due to an infiltration of halogen gas. Particularly, when a ferroelectric capacitor size becomes small, there is a large percentage that the capacitor receives these process damages from the periphery of the ferroelectric capacitor. Accordingly, a polarization amount is degraded. Further, the reduction of the ferroelectric capacitor size brings about fatigue degradation of the ferroelectric capacitor, retention degradation, and imprint degradation.

Therefore, conventionally, hydrogen barrier is provided in the upper electrode using a film of IrOₓ or the like, and the periphery of the ferroelectric capacitor is covered with a hydrogen barrier film of Al₂O₃, SiN and the like, thereby suppressing these process damages (for example, see Japanese Patent Application Laid-open No. 2003-174146).

As explained above, because the FeRAM of the conventional COP configuration suppresses the influence of the process damages, the density of defects near the interface between the upper electrode and the ferroelectric film can be decreased. However, not only the defects of the upper electrode but also the defects near the interface between the lower electrode and the ferroelectric film give a large influence to the characteristics of the ferroelectric capacitor such as the polarization characteristic, the fatigue characteristic, the retention characteristic, and the imprint characteristic. Therefore, it is important to form an interface between the lower electrode and the ferroelectric film having low defect density, as much as possible.

Defects which are present at the interface between the lower electrode and the ferroelectric film include a cation defect, an oxygen defect, a hydrogen coupling, a hetero-phase, and excess element. These defects become a trap site of carriers, and form a space charge, thereby degrading initial characteristic and reliability of the ferroelectric capacitor.

Further, along the miniaturization of the ferroelectric capacitor, there is a considerable influence of stress from the external configuration to the upper and lower electrodes and to the side surfaces and the whole of the ferroelectric film, thereby interrupting the switching. Particularly, there is a large stress from the hydrogen barrier film of Al₂O₃, SiN and the like covering the periphery of the ferroelectric capacitor, thereby degrading the electric characteristic of the ferroelectric capacitor.

Further, the conventional FeRAM does not take into account the easiness of a polarization inversion due to a change of the external electric field in each domain within the ferroelectric film. Therefore, there has been a demand for a configuration of a ferroelectric capacitor easily generating a polarization inversion along a change of an external electric field.

### SUMMARY OF THE INVENTION

A semiconductor memory device according to an embodiment of the present invention comprises: a field-effect transistor formed on a substrate; an interlayer insulation film formed on the substrate on which the field-effect transistor is formed; and a ferroelectric capacitor including a lower electrode connected via a plug to one of source/drain regions of the field-effect transistor, and formed on the interlayer insulation film, a ferroelectric film having a perovskite crystal structure used as a basic structure, and an upper electrode, wherein a lattice matching region in which a lattice of the ferroelectric film is matched with a lattice of the lower electrode is formed in a range of a predetermined thickness of the ferroelectric film from the lower electrode.

A method of manufacturing a semiconductor memory device according to an embodiment of the present invention comprises: forming a field-effect transistor on a substrate; forming an interlayer insulation film covering the field-effect transistor on the substrate; forming a contact hole connecting to source/drain regions of the field-effect transistor; embedding a contact plug into the contact hole; forming a lower electrode made of a conductive material on the interlayer insulation film on which the contact plug is formed; forming a ferroelectric film including a lattice matching region to match a lattice of the ferroelectric film with a lattice of the lower electrode, on the lower electrode; and forming an upper electrode on the ferroelectric film.

### BRIEF DESCRIPTION OF THE DRAWINGS

FIG. 1 is a partial cross-sectional view schematically depicting one example of a configuration of a semiconductor memory device according to a first embodiment of the present invention;

FIG. 2A to FIG. 2H are schematic cross-sectional views of one example of a procedure of a method of manufacturing the semiconductor memory device according to the first embodiment;

FIGS. 3A and 3B are cross-sectional views of another example of a procedure of a method of manufacturing the semiconductor memory device according to the first embodiment;

FIG. 4 is a partial cross-sectional view schematically depicting one example of a configuration of a semiconductor memory device according to a second embodiment of the present invention;

FIGS. 5A and 5B are schematic cross-sectional views of one example of a procedure of a method of manufacturing the semiconductor memory device according to the second embodiment;

FIGS. 6A and 6B are partial cross-sectional views schematically depicting one example of a configuration of a ferroelectric capacitor portion of a semiconductor memory device according to a third embodiment of the present invention;

FIGS. 7A to 7C are schematic cross-sectional views of one example of a procedure of a method of manufacturing the semiconductor memory device according to the third embodiment;

FIG. 8 is a partial cross-sectional view schematically depicting one example of a configuration of a ferroelectric capacitor part of a semiconductor memory device according to a fourth embodiment of the present invention;

FIGS. 9A to 9C are schematic diagrams of a state of a general domain reversal in a ferroelectric film; and

FIG. 10 is a schematic cross-sectional view of another example of a configuration of the semiconductor memory device according to the fourth embodiment.

### DETAILED DESCRIPTION OF THE PREFERRED EMBODIMENTS

Exemplary embodiments of a semiconductor memory device and a manufacturing method thereof according to the present invention will be explained below in detail with reference to the accompanying drawings. The present invention is not limited to the embodiments. In addition, cross-sectional views of the semiconductor memory device according to the embodiments are schematic, and a relationship between a thickness and a width of a layer and a rate of each layer are different from actual relationships. Further, the thickness of each layer shown in the embodiments is only illustrative and is not limited thereto.

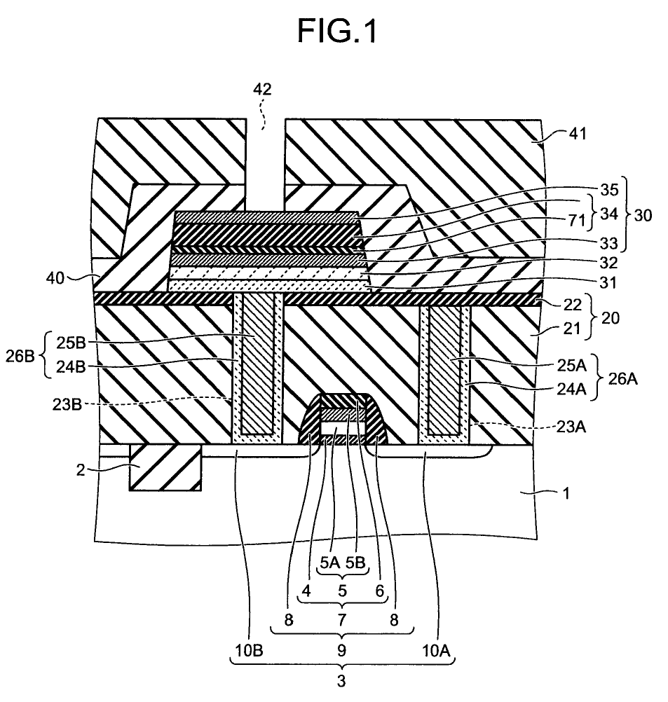

FIG. 1 is a partial cross-sectional view schematically depicting one example of a configuration of a semiconductor memory device according to a first embodiment of the present invention. An element-isolation insulating film 2 including a silicon oxide film and the like is formed within an upper surface of a semiconductor substrate 1 such as a P-type silicon substrate. A metal insulator semiconductor (MIS) field-effect transistor (MISFET) 3 having a metal/insulator/semiconductor junction is formed within an element formation region prescribed by the element-isolation insulating film 2. The MISFET 3 includes a gate structure 9 including gate sidewall films 8 formed on both side surfaces in a line width direction of a gate-stacked film 7, which has a stack of a gate insulation film 4, a gate electrode 5 becoming a word line, and a gate cap film 6, and source/drain regions 10A and 10B forming a pair of regions sandwiching a lower channel region of the gate structure 9. For the gate insulation film 4, a silicon oxide film can be used, for example. For the gate electrode 5, a polycide structure having a polycrystalline silicon film 5A and a WSi₂ film stacked together can be used, for example. For the gate cap film 6 and the gate sidewall film 8, a silicon nitride film can be used, for example.

A first interlayer insulation film 20 having a flat surface with a thickness of 1,050 to 1,350 nanometers is formed on the semiconductor substrate 1 on which the MISFET 3 is formed as described above. The first interlayer insulation film 20 has a configuration having a silicon oxide film 21, and a three-layer stacked film 22 of a silicon oxide film, a silicon nitride film, and a silicon oxide film stacked in this order, from a lower side. Contact holes 23A and 23B are formed to pierce through a thickness direction at a position corresponding to the source/drain regions 10A and 10B of the first interlayer insulation film 20. Diffusion prevention films 24A and 24B having a thickness of 5 to 10 nanometers preventing a metal constituting contact plugs 26A and 26B from being diffused into the first interlayer insulation film 20, and plugs 25A and 25B, are formed within the contact holes 23A and 23B. The source/drain region 10B is formed with the contact plug 26B to pierce through the whole of the first interlayer insulation film 4. The other source/drain region 10A is formed with the contact plug 26A to pierce through only the lowest-layer silicon oxide film 21. A TiN film or the like can be used for the diffusion prevention films 24A and 24B, and W and doped polycrystalline silicon or the like can be used for the plugs 25A and 25B.

An adhesive film 31 and a capacitor barrier film 32 are formed sequentially in a peripheral region including an upper surface of the contact plug 26B piercing through the whole of the first interlayer insulation film 20 having a four-layer structure. A ferroelectric capacitor 30 sequentially stacked with a lower electrode 33, a ferroelectric film 34 (hereinafter, also “PZT film 34”), and an upper electrode 35 is formed on the upper part of an adhesive film 31 and the capacitor barrier film 32.

The adhesive film 31 increases adhesiveness between the first interlayer insulation film 20 and the capacitor barrier film 32, and includes a conductive film of TiAl or the like having a thickness of about 30 nanometers. The capacitor barrier film 32 is formed between the ferroelectric capacitor 30 and the contact plug 26B, and is configured by a conductive film having a thickness of about 5 nanometers, suppressing a diffusion of oxygen from the ferroelectric film 34 to the contact plug 26B, and having a hydrogen barrier. TiAlN, TaSiN, TiN, TiSiN or the like can be mentioned as materials of the capacitor barrier film 32. The lower electrode 33 is configured by a conductive film of high oxidization-resistance having a thickness of about 100 nanometers. Ir, Pt, IrOx or the like can be used for the lower electrode 33.

When Pt is used for the lower electrode 33, an SRO film (not shown) is sometimes formed on the Pt to suppress the occurrence of fatigue degradation decreasing a polarization amount due to a repetition of a polarization inversion, at the interface between the lower electrode 33 and PZT used for the ferroelectric film 34. Particularly, when a PZT film is formed by sputtering, interface defect increases. Therefore, the SRO film is preferably introduced. When the SRO film is formed at the upper electrode 35 side, the SRO film is sometimes formed between the lower electrode 33 and the ferroelectric film 34, regardless of a material of the lower electrode 33, from the viewpoint of symmetry of the structure of the ferroelectric capacitor 30. Further, the capacitor barrier film 32 does not need to be provided when the ferroelectric film 34 can be grown at a low temperature.

For the ferroelectric film 34, there is used a thin film having a thickness of about 100 nanometers made of a ferroelectric substance such as PZT, BIT, and SBT having a crystal structure based on a perovskite structure. For the upper electrode 35, there is used a film having a thickness equal to or smaller than 100 nanometers which does not degrade the ferroelectric capacitor characteristic considerably, or does not lower the reliability of the ferroelectric capacitor 30 considerably. For materials of the upper electrode 35, there are stacked structures of Ir, IrOₓ, Pt, Ru, and RuOₓ, or a noble metal oxide of Ir, Pt, Ru IrOₓ, and RuOₓ, and a conductive oxide such as SRO, LNO, and LSCO.

A hydrogen barrier film 40 made of Al₂O₃, SiN and the like having a thickness of about 50 nanometers is formed to cover the front surface and side surface of the ferroelectric capacitor 30 on the first interlayer insulation film 20. A second interlayer insulation film 41 made of a silicon oxide and the like having a thickness of 100 to 200 nanometers is formed on the hydrogen barrier film 40. An upper layer wiring is formed on the second interlayer insulation film 41, and is electrically connected to the lower layer wiring and the upper electrode via a via-hole 42. Because the characteristic of the ferroelectric capacitor 30 is in the first embodiment, explanations of other parts will be omitted.

A defect suppressing region 71 (a lattice adjustment region) introduced with a dopant to suppress an oxygen defect in comparison with loss in other parts of the ferroelectric film 34 is provided near the interface between the ferroelectric film 34 and the lower electrode 33. When a composition formula of the ferroelectric film 34 made of a perovskite structure is ABO₃, for example, the defect suppressing region 71 is configured such that when O easily vaporizes when the element A vaporizes, the element A is substituted by another element X which has a volatility lower than that of the element A, or the element B is substituted by the element Y having a larger valence than the valence of the element B so that O does not easily dissociate by electric force even when the element A escapes.

Further, it is generating an effect of relaxing stress of the ferroelectric film 34 applied to the lower electrode 33, by matching a lattice constant of the defect suppressing region 71 with a lattice constant of the lower electrode 33. Therefore, in addition to the suppressing of the oxygen defect, the occurrence of a defect such as a lattice defect generated near the interface between the ferroelectric film 34 and the lower electrode 33 can be suppressed. In this case, preferably, a mismatch between the lattice constant of the defect suppressing region 71 and the lattice constant of the lower electrode 33 is equal to or smaller than 3%. When the mismatch between the lattice constants is larger than 3%, the density of the crystal defect of the defect suppressing region 71 becomes equal to the conventional density.

The above configuration is explained based on a detailed example. When PZT constitutes the ferroelectric film 34, Pb²⁺ occupying the A site in the perovskite structure vaporizes easily, and O²⁻ also escapes accordingly. By substituting a part of the A site with La³⁺ or Nb⁵⁺ that does not vaporize from a solid object easily, O²⁻ does not vaporize easily, thereby oxygen defect does not occur easily. By substituting a part of Zr⁴⁺ and Ti⁴⁺ occupying the B site with Mn, even when Pb²⁺ of the A site vaporizes, a plus charge of the Mn ion occupying the B site stops O²⁻ from escaping, thereby minimizing the oxygen defect. That is, when the ferroelectric film 34 is PZT, the defect suppressing region 71 added with the elements of La, Nb, Mn or the like is provided near the interface between the ferroelectric film 34 and the lower electrode 33.

To match the lattice constant of PZT with the lattice constant of the lower electrode 33, a part of the A site of PZT is substituted with at least one type of element selected from a group of metals Ba, Sr, Ca, and La. Alternately, or in addition to this, a part of the B site is substituted with at least one type of element selected from a group of metals Co, Ni, W, Fe, Hf, Sn, Zn, Ta, Mg, Mn, and Nb.

Preferably, a thickness of the defect suppressing region 71 is 5 to 20 nanometers. When the thickness is smaller than 5 nanometers, the oxygen defect cannot be effectively suppressed. When the thickness is larger than 20 nanometers, the ferroelectric characteristic of the ferroelectric film 34 is degraded.

As explained above, to suppress the oxygen defect, at least one of the element to substitute the constituent element of the ferroelectric film 34 and/or the element to decrease the mismatch of the lattice constants between the ferroelectric film 34 and the lower electrode 33, are doped near the interface between the ferroelectric film 34 and the lower electrode 33, thereby providing the defect suppressing region 71 having a thickness of 5 to 20 nanometers. With this arrangement, the occurrence of defects such as the oxygen defect and the lattice defect near the interface between the ferroelectric film 34 and the lower electrode 33 can be decreased.

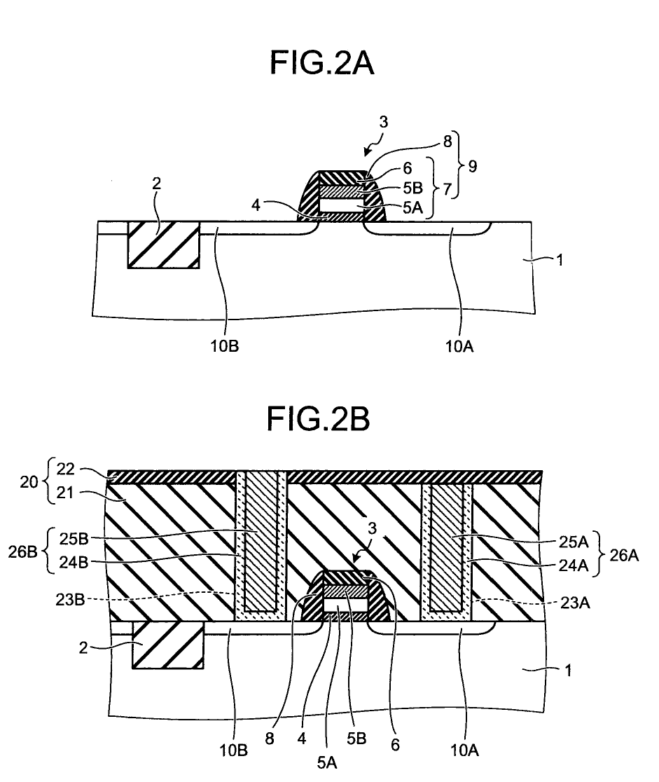

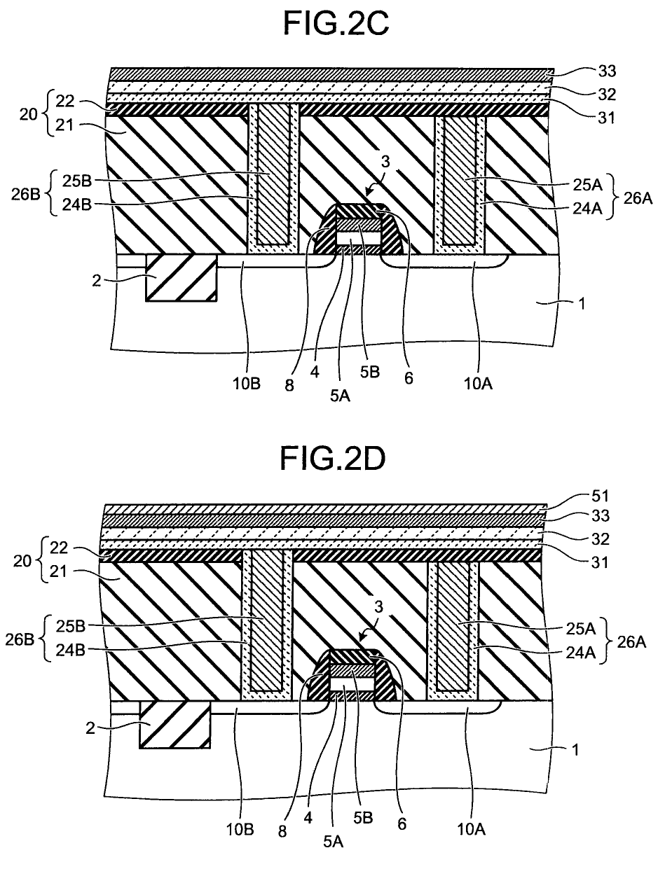

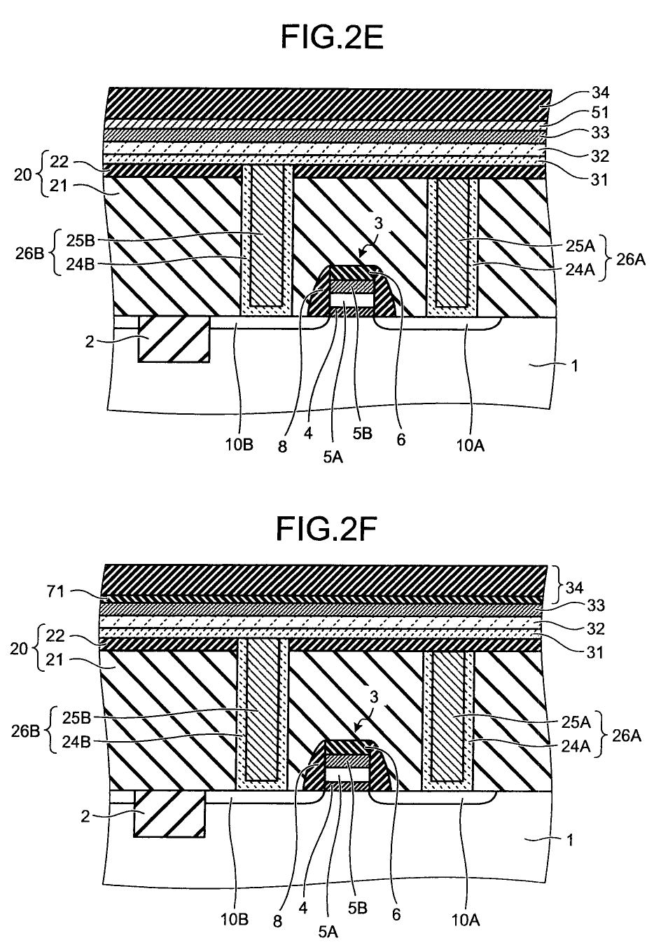

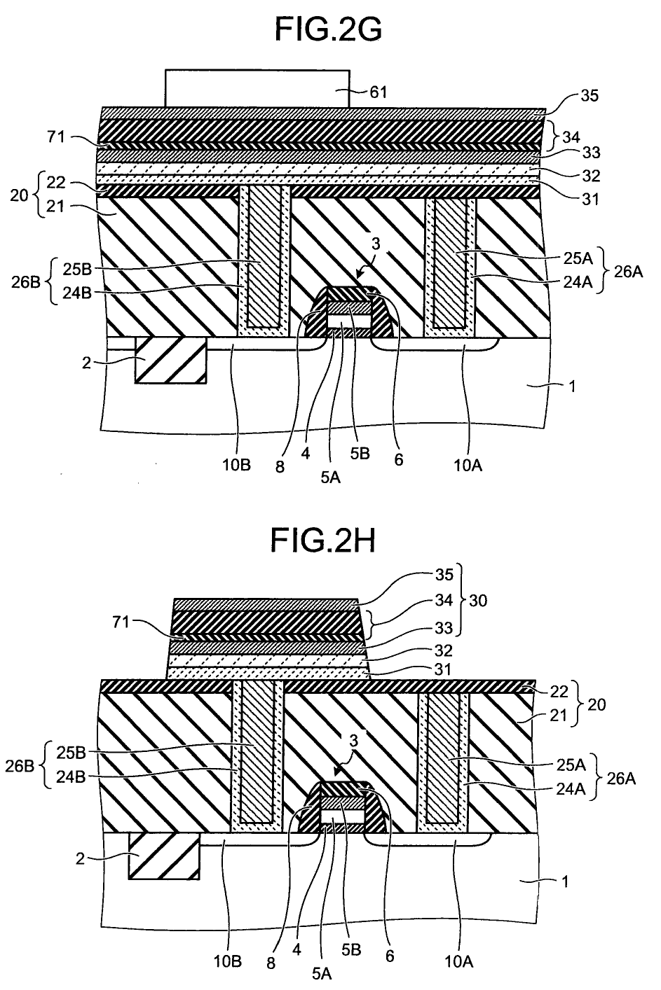

A method of manufacturing the semiconductor memory device is explained next. FIGS. 2A to 2H are schematic cross-sectional views of one example of a procedure of a method of manufacturing the semiconductor memory device according to the first embodiment. An example of using PZT for the ferroelectric film 34 is explained below. First, the element-isolation insulating film 2 having a predetermined pattern is formed on the surface of the semiconductor substrate 1 such as a P-type silicon substrate, by a shallow trench isolation (STI) method or the like. Thereafter, the MISFET 3 is formed as described below (FIG. 2A) on a region surrounded by the element-isolation insulating film 2 on the semiconductor substrate 1.

For example, the gate insulation film 4 such as a silicon oxide film, the n-type polycrystalline silicon film 5A doped with arsenic, a WSiₓ film 5B, and the gate cap film 6 such as a silicon nitride film are sequentially stacked on the semiconductor substrate 1. The stacked films are processed in a predetermined shape by a normal lithography method and a reactive ion etching (RIE) method, thereby forming the gate-stacked film 7 including the gate insulation film 4, the gate electrode 5, and the gate cap film 6. Ion is implanted using the gate-stacked film 7 as a mask, and the ion-implanted result is heat treated to form predetermined conductive source/drain regions 10A and 10B on the surface of the semiconductor substrate at both sides in a line width direction of the gate-stacked film 7. Thereafter, an insulation film such as a silicon nitride film is formed on the semiconductor substrate 1. The insulation film deposited on the surface of the semiconductor substrate 1 is removed by anisotropic etching using the RIE method, to leave the insulation film on only the side surface in the line width direction of the gate-stacked film 7, thereby forming the gate sidewall film 8. As a result, the gate structure 9 including the gate insulation film 4, the gate electrode 5, the gate cap film 6, and the gate sidewall film 8 is formed on the semiconductor substrate 1. The MISFET 3 is formed in a predetermined region surrounded by the element-isolation insulating film 2.

The silicon oxide film 21 having a thickness of 600 to 700 nanometers is then formed by the CVD method on the whole surface of the semiconductor substrate 1 on which the MISFET 3 is formed. The upper surface of the silicon oxide film 21 is flattened by a chemical mechanical polishing (CMP) method. Thereafter, the contact hole 23A connecting to the source/drain region 10A of the MISFET 3 is formed on the silicon oxide film 21, and a thin Ti film having a thickness of 5 to 10 nanometers is formed on the inner wall and the side surface of the contact hole 23A, by the sputtering method or the CVD method. A TiN film becoming the diffusion prevention film 24A is formed to cover the inner wall and the bottom surface of the contact hole 23A by heat treatment in a forming gas. A W film is formed on the silicon oxide film 21 by the CVD method, and the W is removed by the CMP method from a region other than the contact hole 23A. W is embedded into the contact hole 23A, thereby forming the plug 25A. As a result, the contact plug 26A including the diffusion prevention film 24A and the plug 25A is formed within the contact hole 23A.

The stacked film 22 including a silicon oxide film having a thickness of 200 to 300 nanometers, a silicon nitride film having a thickness of 50 nanometers, and a silicon oxide film having a thickness of 200 to 300 nanometers is then formed on the whole surface of the silicon oxide film 21 on which the contact plug 26A is formed. The upper surface of the stacked film 22 is flattened by the CMP method. The silicon oxide film 21, and the stacked film 22 including the silicon oxide film, the silicon nitride film, and the silicon oxide film form the first interlayer insulation film 20. The contact hole 23B connecting to the other source/drain region 10B of the MISFET 3 is formed on the first interlayer insulation film 20. Thereafter, a TiN film becoming the diffusion prevention film 24B is formed in a similar manner to that of the forming the contact plug 26A. W becoming the plug 25B is embedded into the contact hole 23B, thereby forming the contact plug 26B (FIG. 2B) connected to the ferroelectric capacitor 30 to be formed in the subsequent process.

The adhesive film 31 made of TiAl or the like having a film thickness of about 30 nanometers, and the capacitor barrier film 32 made of TiAlN or the like having a thickness of about 5 nanometers are formed in this order by the sputtering method on the first interlayer insulation film 20 on which the contact plug 26B is then formed. The TiAl film can be formed using a TiAl alloy target. The TiAlN film can be formed using a TiAl alloy target by a reactive sputtering method in a gas atmosphere having N₂ added to Ar. The TiAlN film can have its crystallinity improved by preparing the film at high-temperature or by heat treatment, and can have stress relaxed. Thereafter, the lower electrode 33 made of Ir or the like having a film thickness of about 100 nanometers is formed on the capacitor barrier film 32 by the sputtering method. When Ir is used, preferably, the lower electrode 33 is formed by sputtering at or above 300° C. to prevent formation of a hillock (FIG. 2C).

On the lower electrode 33 formed in this way, a substitution element film 51 including at least one type of element selected from a group of metals Ba, Sr, Ca, and La capable of substituting the A site of PZT and at least one type of element selected from a group of metals Co, Ni, W, Fe, Hf, Sn, Zn, Ta, Mg, Mn, and Nb capable of substituting the B site of PZT, is formed to form a continuous film in a thickness equal to or smaller than 5 nanometers (FIG. 2D). However, in this case, preferably, the element substituting the constituent element of PZT is the element not substantially degrading the capacitor characteristic of PZT. The substitution element film 51 can be the above-described metal film or can be an oxide film having the above metal oxidized. In the present example, the substitution element film 51 is a metal film. When the substitution element film 51 is formed to have a larger thickness than 5 nanometers, a metal oxide (NbO, MnO, BaO, or the like) is formed in the ferroelectric film 34 after the diffusion between the substitution element film 51 and the PZT film formed later, and the ferroelectric capacitor characteristic is degraded. Therefore, the thickness of the substitution element film 51 is preferably equal to or smaller than 5 nanometers.

Thereafter, the PZT film 34 having a thickness of 95 to 100 nanometers is formed on the substitution element film 51 using a metalorganic chemical vapor deposition (MOCVD) method (FIG. 2E). The film formed by the MOCVD method has little defect within the film, and also has little defect at the electrode interface. Therefore, this film has a satisfactory polarization characteristic, and has high reliability in the fatigue characteristic, the imprint characteristic, and the retention characteristic. Accordingly, the MOCVD method is used to form the film. Further, the MOCVD method has a satisfactory step coverage in the electrode structure, excellent controllability of composition, can obtain a uniform high-quality film in a large area, has a high deposition rate, and can form a thin film of the PZT film 34 (a low-voltage operation is possible). Therefore, the MOCVD method is preferably used to form the PZT film 34. Further, crystallinity of the PZT film 34 can be increased on Ir that is the lower electrode 33, and the composition can be controlled easily. In forming the PZT film 34, a liquid raw material is generally used for the source. For example, the film is formed, using THF (tetrahydrofuran) as a solvent, using Pb(dpm)₂/THF, Ti(iPr)₂(dpm)₂/THF, Zr(iPr)₂(dpm)₂/THF as source materials, and using oxygen as a reaction gas at a temperature of 600° C. or above.

After the PZT film 34 is formed, the film is heat treated at a temperature of 400 to 600° C. (FIG. 2F). The time of performing the heat treatment is a period during which the defect suppressing region 71 is formed in a thickness of 5 to 20 nanometers from the lower electrode 33. With this arrangement, impurity such as carbon is removed from the PZT film 34, and the PZT film 34 and the substitution element film 51 diffuse mutually, thereby forming the defect suppressing region 71 compensating for the defect. That is, PZT becomes a substitutable element in the range of a film thickness of 5 to 20 nanometers from the interface between the lower electrode 33 and the PZT film 34, and each element is partially substituted, thereby forming the defect suppressing region 71 having a perovskite structure of (Pb, X)(Zr, Ti, Y)O₃ as a composition formula. However, the element is at least one type of element selected from a group of metals X=Ba, Sr, Ca, La, Nb, at least one type of element selected from a group of metals Y=Co, Ni, W, Fe, Hf, Sn, Zn, Ta, Mg, Mn, Nb, and a relationship of (density of X)=(density of Y)=0 is not satisfied. Based on this structure, according to the first embodiment, the defect density of the oxygen defect and the lattice loss near the interface between the defect suppressing region 71 and the lower electrode 33 can be suppressed to a lower level than the conventional level.

The upper electrode 35 made of Pt or the like having a thickness equal to or smaller than 100 nanometers is formed on the PZT film 34 by a preparation method such as the sputtering method. A mask material 61 having a predetermined shape configured by a hard mask made of a resist or a silicon oxide film is formed on the upper electrode 35 (FIG. 2G). Thereafter, the upper electrode 35 is patterned by etching using the mask material 61 as a mask, thereby forming the ferroelectric capacitor 30 (FIG. 2H). Specifically, the ferroelectric capacitor 30 is processed by the RIE method, using the mask material 61 formed in a ferroelectric-capacitor processing pattern. In the FeRAM capacitor, in addition to the ferroelectric film 34 such as PZT and SBT, a noble metal electrode that can withstand a filming of a crystal oxide needs to be processed. Therefore, depending on the situation, an RIE process is performed using an etching gas of halogen gas at a temperature equal to or higher than 200° C. In this case, the etching is performed in the order of the upper electrode 35, the PZT film 34, and the lower electrode 33 using the mask material 61. Further, the capacitor barrier film 32 and the adhesive film 31 used in the first embodiment are sequentially etched. The etching gas used to etch the capacitor barrier film 32 and the adhesive film 31 includes N₂, O₂, Co, Cl₂, and CF₄. The ferroelectric capacitor 30 processed in this process has a structure via a hydrogen barrier layer such as Al₂O₃ around the connection with the contact plug 26B. Thereafter, the mask material 61 is removed.

The ferroelectric capacitor 30 is heat treated in the atmosphere containing oxygen at a temperature of 400 to 600° C., thereby removing a damage generated during the processing. Thereafter, the hydrogen barrier film 40 having a thickness of about 500 nanometers is formed to surround the whole of the etched ferroelectric capacitor 30, as shown in FIG. 1. The second interlayer insulation film 41 made of a silicon oxide film having a thickness of about 100 to 200 nanometers is formed on the hydrogen barrier film 40. The via-hole 42 to connect to the upper electrode 35 of the adjacent ferroelectric capacitor 30 (not shown) is formed. A wiring is provided in the via-hole 42, thereby providing the semiconductor memory device.

In the above explanations, FIG. 2E depicts that the substitution element film 51 containing a substitutable element is deposited on the lower electrode 33 in the thickness up to 5 nanometers. The PZT film 34 is formed on this, and thereafter, both are diffused. Any method can be used when the defect suppressing region 71 having a composition preventing a defect of the oxygen defect or the like can be formed near the interface between the PZT film 34 and the lower electrode 33.

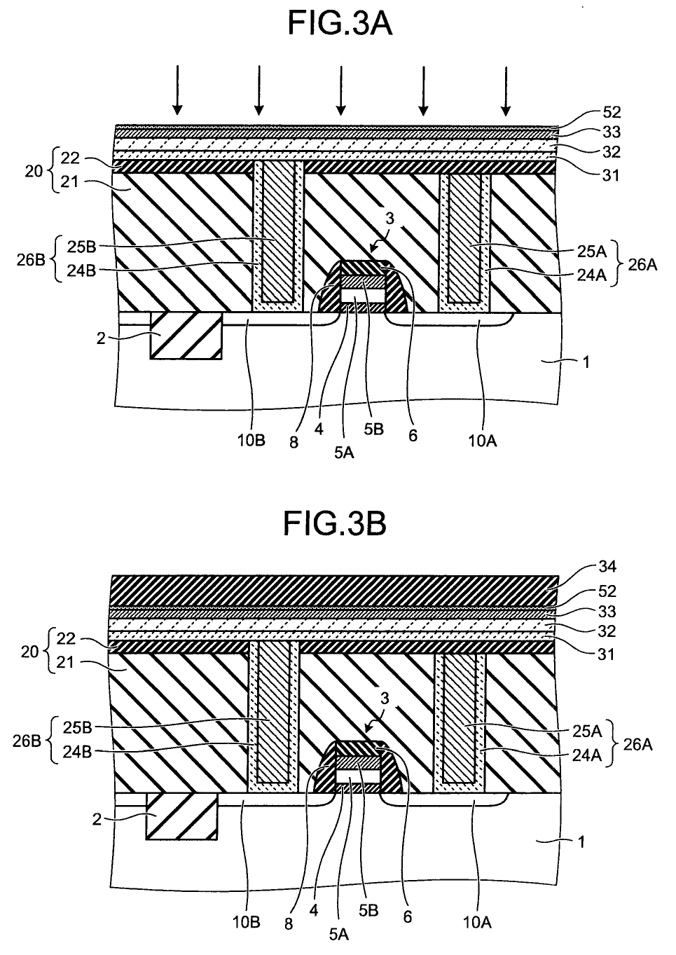

FIGS. 3A and 3B are cross-sectional views of another example of a procedure of a method of manufacturing the semiconductor memory device according to the first embodiment. In this example, as shown up to FIG. 2C, after the lower electrode 33 is formed, an element substitutable with the element constituting the PZT film to be configured later is ion implanted near the surface of the lower electrode 33, thereby forming a substitutable-element implantation region 52 (FIG. 3A). In this case, the ion-implanted element is the element substitutable with the element constituting the PZT film formed later. As described above, this element is at least one type of element selected from a group of metals Ba, Sr, Ca, La, and Nb for a part of the A site of PZT and at least one type of element selected from a group of metals Co, Ni, W, Fe, Hf, Sn, Zn, Ta, Mg, Mn, and Nb for a part of the B site of PZT. The amount of ion implantation is set to a range of thickness 5 to 20 nanometers from the interface of the lower electrode of the PZT film by the subsequent heat treatment, and a concentration of the substitutable element is selected to become 10 to 20 at. %.

The PZT film 34 is then formed on the lower electrode 33 by the MOCVD method (FIG. 3B). A heat treatment is performed so that the element implanted in the substitutable-element implantation region 52 of the lower electrode 33 is diffused near the interface between the PZT film 34 and the lower electrode 33, thereby forming the defect suppressing region 71 at a lower part of the PZT film 34, in a similar manner to that shown in FIG. 2F. Thereafter, the process shown in FIG. 2G and after is performed. The ferroelectric capacitor 30 having the defect suppressing region 71 can be also obtained by the above method.

In the above explanations, a dopant is introduced near the interface between the ferroelectric film 34 and the lower electrode 33 to minimize the occurrence of defects such as the oxygen defect and the lattice defect, thereby decreasing the defect density near the interface between the ferroelectric film 34 and the lower electrode 33. Alternatively, the dopant can be introduced into the lower electrode 33 to bring the lattice constant of the lower electrode 33 close to the lattice constant of the ferroelectric film 34. When the lattice constant of the lower electrode 33 is brought close to the lattice constant of the ferroelectric film 34, the ferroelectric film 34 can grow receiving the influence of the crystal structure of the lower electrode 33 as a base film, even when the growing ferroelectric film 34 is a polycrystalline film. Therefore, the density of the crystal defect near the interface between the ferroelectric film 34 and the lower electrode 33 can be decreased. In this case, Ir can be used for the lower electrode 33. When the Ir is doped with a metal such as Ru, Ti, Pd, and Pt, the lattice constant of Ir can be brought close to the lattice constant of the ferroelectric film 34 such as a PZT film. When these metals form a solid solution with Ir, the interface stress can be suppressed.

In the above explanations, while the defect suppressing region 71 is provided near the interface between the ferroelectric film 34 and the lower electrode 33, the defect suppressing region can be also provided near the interface between the ferroelectric film 34 and the upper electrode 35.

According to the first embodiment, a dopant is introduced in the ferroelectric film 34 near the interface between the ferroelectric film 34 and the lower electrode 33, in the capacitor structure of the FeRam or a hybrid memory. With this arrangement, the density of the oxygen defect and the lattice defect in the ferroelectric film 34 near the interface between the ferroelectric film 34 and the lower electrode 33 can be decreased from a defect density of the conventional configuration of the semiconductor memory device. As a result, the occurrence of a charge such as a space charge interrupting the polarization inversion of the ferroelectric substance in the ferroelectric film 34 can be suppressed, and the ferroelectric capacitor characteristic can be improved. Further, the occurrence of a charge such as the space charge in the ferroelectric film 34 is suppressed. Therefore, the polarization inversion can be easily performed when the direction of the external electric field applied to the ferroelectric film 34 changes.

In the first embodiment, a dopant is introduced near the interface between the ferroelectric film and the lower electrode to form a defect suppressing region having a composition different from that of the ferroelectric film. On the other hand, in a second embodiment of the present invention, a solid solution composition near the interface between the ferroelectric film and the lower electrode is changed.

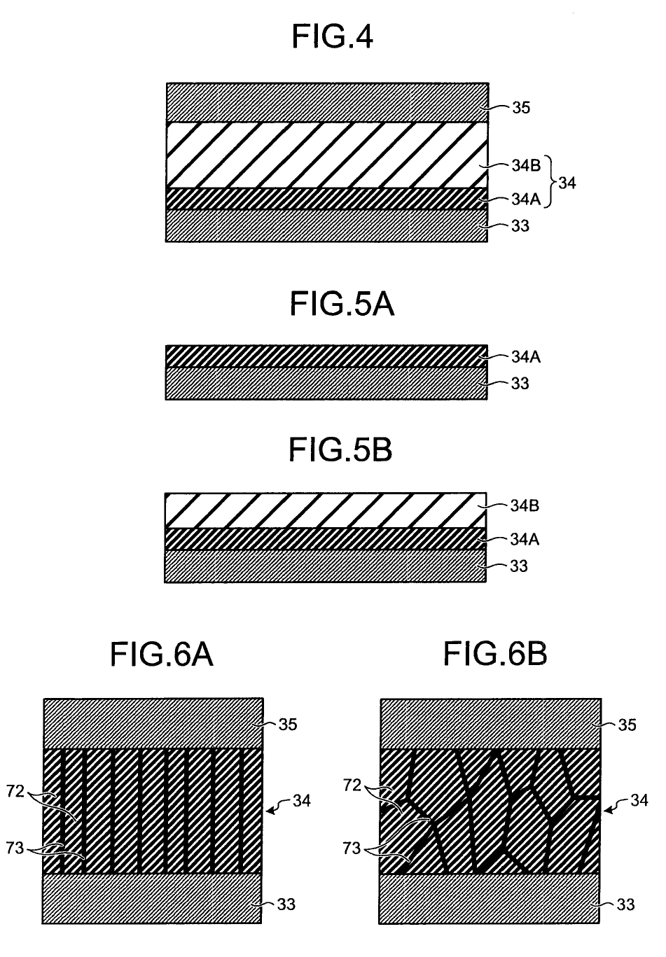

FIG. 4 is a partial cross-sectional view schematically depicting one example of a configuration of a semiconductor memory device according to the second embodiment. Configurations of other parts than the ferroelectric film and the upper and lower electrodes of the ferroelectric capacitor 30 are similar to those shown in FIG. 1 according to the first embodiment. Therefore, FIG. 4 depicts only configurations of the lower electrode 33, the upper electrode 35, and the ferroelectric film 34 sandwiched between these electrodes, and the configurations identical to those of the first embodiment are omitted.

In the semiconductor memory device according to the second embodiment, the ferroelectric film 34 according to the first embodiment includes a lower ferroelectric film 34A of a composition having a lattice constant near the lattice constant of the material constituting the lower electrode 33 on the lower electrode 33, and an upper ferroelectric film 34B having a composition of a better ferroelectric-capacitor characteristic than the lower ferroelectric film 34A on the lower ferroelectric film 34A. In the second embodiment, constituent elements identical to those in the first embodiment are denoted by like reference numerals and explanations thereof will be omitted.

Preferably, a mismatch between the lattice constants of the lower ferroelectric film 34A and the lower electrode 33 is equal to or smaller than 3%. When the mismatch between the lattice constants is larger than 3%, the density of the crystal defect of the lower ferroelectric film 34A becomes equal to the conventional density. To increase the match between the lattice constant of the lower ferroelectric film 34A and the lattice constant of the lower electrode 33, preferably, a difference between the lattice constants in each crystal direction in the crystal structure is small. Therefore, preferably, the semiconductor memory device has a rhombohedral system or a cubic system. When other crystal systems are used, lengths of the crystal axes are mutually the same.

Preferably, a thickness of the lower ferroelectric film 34A is 5 to 20% of the total thickness of the ferroelectric film 34. This is because when the lower ferroelectric film 34A has a thickness of 5 to 20% of the total thickness of the ferroelectric film 34, the ferroelectric film 34 having a satisfactory matching with the lower electrode 33 can be formed, and the occurrence of a defect near the interface between the ferroelectric film 34 and the lower electrode 33 can be suppressed. When the thickness is 5 to 20%, the total ferroelectric-capacitor characteristic of the ferroelectric film 34 is not substantially degraded. The lower ferroelectric film 34A corresponds to a different composition region and a lattice matching region in the appended claims.

For example, when Ir is used for the lower electrode 33, and also PZT is used for the ferroelectric film 34, PZT of a composition having a relationship of Ti/Zr<55/45 becoming a morphotropic boundary layer or a rhombohedral is used for the lower ferroelectric film 34A, and tetragonal PZT of a composition having a relationship of Ti/Zr≧55/45 is used for the upper ferroelectric film 34B. That is, the lower ferroelectric film 34A is a PZT film of a composition having much Zr (having little Ti), and the upper ferroelectric film 34B becomes a PZT film of a composition having little Zr (having much Ti). As explained above, when the lower ferroelectric film 34A is a PZT film of a rhombohedral, the lattice constant of the lower ferroelectric film 34A can be highly consistent with the lattice constant of Ir. As a result, the occurrence of a defect in the ferroelectric film can be suppressed as compared with the occurrence of a defect when the lattice of the lower ferroelectric film 34A is inconsistent with the lattice of the lower electrode 33.

A method of manufacturing the semiconductor memory device having the above configuration is explained next. FIGS. 5A and 5B are schematic cross-sectional views of one example of a procedure of a method of manufacturing the semiconductor memory device according to the second embodiment. Only a manufacturing part of the ferroelectric film 34 different from the manufacturing method explained in the first embodiment is explained. An example of using PZT for the ferroelectric film 34 is explained, like in the first embodiment.

As explained with reference to FIG. 2A to FIG. 2C in the first embodiment, the first interlayer insulation film 20 is formed on the semiconductor substrate 1 on which the MISFET 3 is formed. The contact plugs 26A and 26B connecting to the source/drain regions 10A and 10B of the MISFET 3 are formed on the first interlayer insulation film 20. The adhesive film 31 made of TiAl or the like, the capacitor barrier film 32 made of TiAlN or the like, and the lower electrode 33 made of Ir are formed, on the first interlayer insulation film 20. Thereafter, a PZT film in a composition range of Ti/Zr<55/45 having a lattice constant near the lattice constant of Ir of the lower electrode 33 is formed in a thickness of 5 to 20 nanometers for the lower ferroelectric film 34A on the lower electrode 33 at a temperature equal to or higher than 600° C., using the MOCVD method (FIG. 5A).

Next, a tetragonal PZT film having a relationship of Ti/Zr≧55/45 is formed for the upper ferroelectric film 34B, on the lower ferroelectric film 34A (FIG. 5B). After the PZT film is formed, heat treatment can be performed to the PZT film in a temperature range of 400 to 600° C. By this heat treatment, impurity such as carbon is removed from the PZT film, and defects of the PZT film can be compensated. As a result, the ferroelectric film 34 can be formed to include the lower ferroelectric film 34A of which lattice constant satisfactorily matches the lattice constant of Ir of the lower electrode 33, and the upper ferroelectric film 34B having a more satisfactory ferroelectric-capacitor characteristic than that of the lower ferroelectric film 34A. Thereafter, the semiconductor memory device is manufactured in the process shown in FIG. 2G and afterward in the first embodiment.

According to the second embodiment, the lower ferroelectric film 34A having a lattice constant near the lattice constant of the lower electrode 33 is formed on the lower electrode 33. The upper ferroelectric film 34B made of a solid solution of the element which is the same as that of the lower ferroelectric film 34A having a better capacitor characteristic than that of the lower ferroelectric film 34A is formed on the lower ferroelectric film 34A. Therefore, the occurrence of a defect in the ferroelectric film 34 near the interface between the ferroelectric film 34 and the lower electrode 33 can be suppressed.

FIGS. 6A and 6B are partial cross-sectional views schematically depicting one example of a configuration of a ferroelectric capacitor portion of a semiconductor memory device according to a third embodiment of the present invention. In FIGS. 6A and 6B, configurations of parts are similar to those in the first embodiment, except the lower electrode 33, the ferroelectric film 34, and the upper electrode 35 of the ferroelectric capacitor 30. Therefore, in FIGS. 6A and 6B, parts similar to those in the first embodiment are omitted.

The semiconductor memory device according to the third embodiment has an insulating-grain-boundary precipitated substance 73 at a grain boundary of a crystal grain constituting the ferroelectric film 34. In the third embodiment, constituent elements identical to those in the first embodiment are denoted by like reference numerals and explanations thereof will be omitted.

FIG. 6A depicts that a crystal grain 72 constituting the ferroelectric film 34 is configured by a pillar crystal extending to a film thickness direction. FIG. 6B depicts the ferroelectric film 34 configured by the crystal grain 72 having a film thickness equal to or smaller than that of the ferroelectric film 34. In both cases, the insulating-grain-boundary precipitated substance 73 such as amorphous PZT, pyrochlore, TiOₓ, and AlOₓ is formed in the grain boundary part of the crystal grain 72.

In a crystal grain of the ferroelectric substance, when a polarization direction changes, a shape of the crystal generally changes. However, when the insulating-grain-boundary precipitated substance 73 shown in the third embodiment is not present in the grain boundary part of the crystal grain 72 of the ferroelectric film 34, the crystal grain 72 of the ferroelectric film 34 are firmly fixed, and the crystal grains cannot move when the polarization direction changes by the change of the external electric field.

On the other hand, as shown in FIGS. 6A and 6B in the third embodiment, when the insulating-grain-boundary precipitated substance 73 is formed in the grain boundary part of the crystal grain 72, the insulating-grain-boundary precipitated substance 73 absorbs displacement of the crystal grain 72 such as expansion and contraction generated following the polarization inversion, and functions as a stress relaxing layer facilitating the occurrence of the displacement. To facilitate the occurrence of the displacement of the crystal grain 72, preferably, the insulating-grain-boundary precipitated substance 73 is formed in the grain boundary part in the direction not parallel with electrode surfaces of the lower electrode 33 and the upper electrode 35.

Further, the insulating-grain-boundary precipitated substance 73 also has a function of relaxing the stress from the hydrogen barrier film 40 formed on the upper surface and the side surface of the ferroelectric capacitor 30. Specifically, while the hydrogen barrier film 40 applies stress to the ferroelectric film 34, because the insulating-grain-boundary precipitated substance 73 is formed between the crystal grains 72 constituting the ferroelectric film 34, the insulating-grain-boundary precipitated substance 73 operates as a buffer of the stress applied to the ferroelectric film 34. As a result, the insulating-grain-boundary precipitated substance 73 has the function of relaxing the stress applied to the crystal grain 72 of the ferroelectric material constituting the ferroelectric film 34.

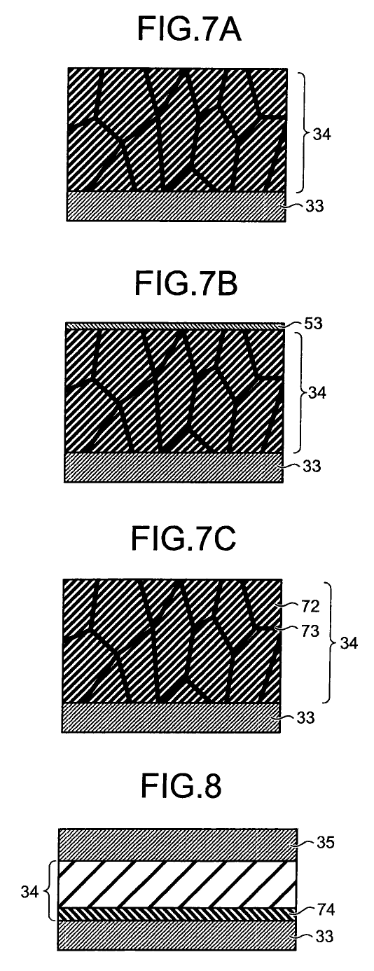

A method of manufacturing the semiconductor memory device having the above configuration is explained next. FIGS. 7A to 7C are schematic cross-sectional views of one example of a procedure of the method of manufacturing the semiconductor memory device according to the third embodiment. Explanations of the manufacturing process same as that in the first embodiment will be omitted. An example of using PZT for the ferroelectric film 34 like in the first embodiment is explained.

As shown in FIGS. 2A to 2C in the first embodiment, the first interlayer insulation film 20 is formed on the semiconductor substrate 1 on which the MISFET 3 is formed. The contact plugs 26A and 26B connecting to the source/drain regions 10A and 10B of the MISFET 3 are formed on the first interlayer insulation film 20. The adhesive film 31 made of TiAl or the like, the capacitor barrier film 32 made of TiAlN or the like, and the lower electrode 33 made of Ir or the like are formed on the first interlayer insulation film 20.

The ferroelectric film 34 made of PZT is formed using the MOCVD method (FIG. 7A). As PZT raw materials used by the MOCVD method, Pb(dpm)₂ is available for the Pb source, Zr(dpm)₄ and Zr(O-tC₄H₉)₄ are available for the Zr source, and Ti(O-iC₃H₇)₄ and Ti(O-iC₃H₇)₂(dpm)₂ are available for the Ti source. By mixing these materials with THF, a mixed result is used for a raw material to be used for solution vaporization. A proper temperature of the substrate is around 600° C., depending on a raw material. N₂O and O₂ are simultaneously used as oxidizing agents to form the film. A crystallization occurs in-situ, and when Ir is used for the lower electrode 33, a PZT<111> oriented crystal film can be obtained on Ir.

A metal film 53 of Al, Ti, TiAl, Bi, Cu and the like is formed in a thickness equal to or lower than 50 Å on the PZT film 34, by the sputtering method (FIG. 7B). Thereafter, the film is heat treated to diffuse the metal film 53 on the PZT film 34 to the grain part of the PZT film 34. After the diffusion, the diffused result is oxygen-annealed to oxidize the metal diffused to the grain part, thereby forming the insulating-grain-boundary precipitated substance 73 (FIG. 7C). As a result, the PZT film 34 becomes in the state that the insulating-grain-boundary precipitated substance 73 is formed between the crystal grains 72 of PZT, as shown in FIG. 6A or FIG. 6B. Thereafter, the semiconductor memory device is manufactured in the process as shown in FIG. 2G afterward in the first embodiment.

The above manufacturing method is only one example, and other methods can be also used to form the insulating-grain-boundary precipitated substance 73 at the crystal grain boundary part of the PZT film 34. For example, the PZT film 34 is formed on the lower electrode 33 in the state that the perovskite phase and the amorphous phase are present in mixture at a temperature equal to or lower than 550° C. Thereafter, a rapid thermal oxidation (RTO) process is performed on the PZT film 34 at or above 600° C. As a result, the perovskite phase is crystallized, and a small amount of the amorphous phase remains on the grain boundary part. The insulating-grain-boundary precipitated substance 73 made of PZT in the amorphous phase can be also formed on the crystal particle grain part.

As a result of checking a hysteresis characteristic of “a charge amount Q−an application voltage V” of the ferroelectric characteristic of the PZT film manufactured in this way, it is clear that when a voltage of 2.5 volts is applied to the PZT film, the polarization amount 2 Pr (remanent polarization×2) is about 49 μC/cm², and the PZT film has about the same levels of a polarization amount and a coercive field on the whole surface of an 8-inch silicon wafer. A low coercive voltage of 0.6 volt is also obtained. A capacitor size is 0.5 to 50 micrometers. The same levels of a remanent polarization amount and a switching charge amount are obtained.

As a result of evaluating the fatigue characteristic of the PZT capacitor in an array corresponding to an area of 50 μm×50 μm, there is no change in the polarization amount until 1×10¹² cycles. A leak current is also low in the 1×10⁻⁷ A/cm² order when a voltage of 2.5 volts is applied.

To relax the influence of stress applied to the ferroelectric film 34 by the hydrogen barrier film 40 such as Al₂O₃, SiN covering the periphery of the ferroelectric capacitor 30, the density of the hydrogen barrier film 40 can be decreased, in addition to providing the insulating-grain-boundary precipitated substance 73 between the crystal grains 72 constituting the ferroelectric film 34. When the film is formed by the sputtering method, for example, density of the hydrogen barrier film 40 can be decreased by increasing the amount of oxygen in AlOₓ in an oxygen-rich gas condition. By an atomic layer deposition (ALD) method, the density can be decreased by forming the film at a low temperature. When the film is formed by the CVD method, stress can be changed by setting SiN to a state of containing excess N.

According to the third embodiment, the insulating-grain-boundary precipitated substance 73 is formed in the grain boundary in the ferroelectric film 34. Therefore, when the polarization inversion occurs, the displacement of the crystal grain 72 constituting the ferroelectric film 34 occurs easily, and the fatigue characteristic of the ferroelectric capacitor 30 is improved. There is also an effect that the stress from the hydrogen barrier film 40 of Al₂O₃ or SiN covering the periphery of the ferroelectric capacitor 30 can be relaxed, and degradation of the electric characteristic of the ferroelectric capacitor 30 can be suppressed. Further, by decreasing the density of the hydrogen barrier film 40, the influence of stress applied from the hydrogen barrier film 40 to the ferroelectric film 34 can be suppressed.

FIG. 8 is a partial cross-sectional view schematically depicting one example of a configuration of a ferroelectric capacitor part of a semiconductor memory device according to a fourth embodiment of the present invention. In FIG. 8, configurations of parts are similar to those in the first embodiment, except the lower electrode 33, the ferroelectric film 34, and the upper electrode 35 of the ferroelectric capacitor 30. Therefore, parts similar to those in the first embodiment will be omitted from FIG. 8.

In the ferroelectric film 34 of the semiconductor memory device according to the fourth embodiment, a different composition region 74 (a lattice matching region) having a ferroelectric composition of which domain is easily inverted is formed in a thickness range of 5 to 20 nanometers from the lower electrode 33. For example, while the whole of the ferroelectric film 34 is made of the same element, the different composition region 74 includes a ferroelectric material of a solid solution having different compositions from those of other regions.

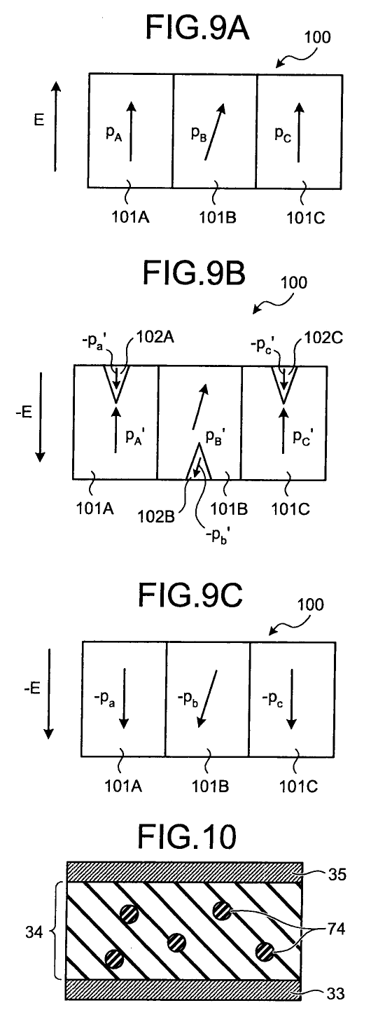

An example of using Ir for the lower electrode 33, and using PZT for the ferroelectric film 34 is explained. PZT has such a characteristic that a domain is easily inverted when the amount of Zr is much. FIGS. 9A to 9C are schematic diagrams of a state of a general domain reversal in the ferroelectric film. FIG. 9A depicts a state that an external electric field E directed from bottom to top in this drawing is applied to the ferroelectric film 100. The ferroelectric film 100 is partitioned into plural regions called domains 101A to 101C. FIG. 9A depicts a state that polarizations P_{A} to P_{C} in the domains 101A to 101C are directed to the external electric field E.

When the external electric field is inverted to −E from top to bottom in this state in the drawing, the polarization inversion in the domains 101A to 101C does not occur at one time. As shown in FIG. 9B, the inversion occurs starting from inversion regions 102A to 102C in which the polarization in the domains 101A to 101C can be easily inverted. That is, in the inversion regions 102A to 102C in which the polarization can be easily inverted, polarizations −Pₐ′ to −P_{c}′ occur in the directions opposite to the directions of polarizations P_{A}′ to P_{C}′ in the original electric field E in other regions. The inversion regions 102A to 102C gradually grow, and as shown in FIG. 9C, the directions of the polarizations in the domains 101A to 101C are finally inverted from the directions shown in FIG. 9A, and become −Pₐ to −P_{c}.

A PZT film is taken up as an example for the ferroelectric film 34. PZT of a composition of which polarization can easily occur and having a relationship of Ti/Zr<55/45 becoming a morphotropic boundary layer or a rhombohedral can be used for the different composition region 74. Tetragonal PZT of a composition having a relationship of Ti/Zr≧55/45 having a better ferroelectric characteristic than that of PZT in the different composition region 74 can be used for the ferroelectric film 34 other than the different composition region 74. That is, a PZT film of a composition having a large amount of Zr (small amount Ti) is used in the different composition region 74 near the interface between the ferroelectric film 34 and the lower electrode 33, and a PZT film of a composition having a small amount of Zr (large amount Ti) is used in the region of the ferroelectric film 34 above the different composition region 74.

When the PZT film 34 having the different compositions is formed in the region near the interface between the ferroelectric film 34 and the lower electrode 33 and in other regions, a polarization is easily inverted in the different composition region 74 because of a large Zr rate. Therefore, the different composition region 74 operates as a inversion domain core. That is, when the direction of the external electric field is changed, the different composition region 74 in which polarization inversion easily occurs becomes the inversion domain core. A polarization gradually occurs in the same direction as the direction of the external electric field, starting from the inversion domain core.

The method of manufacturing a semiconductor memory device having the configuration shown in FIG. 8 can be formed by a method identical to the method explained in the second embodiment, and therefore explanations thereof will be omitted.

In the configuration shown in FIG. 8, when the ferroelectric material constituting the different composition region 74 has the composition in which a polarization inversion easily occurs and also when the composition has a lattice constant near that of the material constituting the lower electrode 33 as explained in the second embodiment, the different composition region 74 can operate as the inversion domain core, and the defect density near the interface between the ferroelectric film 34 and the lower electrode 33 can be decreased from a defect density of the conventional configuration of a semiconductor memory device. As explained in the second embodiment, preferably, the mismatch between the lattice constants of the different composition region 74 and the lower electrode 33 is equal to or smaller than 3%. When the mismatch between the lattice constants is larger than 3%, the density of the crystal defect in the different composition region 74 becomes equal to the conventional density, and a charge such as a space charge interrupting the polarization inversion of the ferroelectric substance occurs, thereby degrading the ferroelectric capacitor characteristic.

Further, the different composition region 74 is not limited to be formed at the lower part of the ferroelectric film 34 as shown in FIG. 8, and can be formed at an optional position. FIG. 10 is a schematic cross-sectional view of another example of a configuration of the semiconductor memory device according to the fourth embodiment. In the example shown in FIG. 10, the different composition region 74 is diffused in the ferroelectric film 34. When the ferroelectric film 34 is configured by PZT for example, Zr-rich PZT or doped PZT as explained in the first embodiment can be diffused in the ferroelectric film 34, to facilitate the domain reversal of the ferroelectric film 34, for the different composition region 74. In this case, during the formation of the ferroelectric film 34 (Ti-rich PZT film), Zr-rich PZT can be locally formed using the photolithographic technique and the etching technique.

According to the fourth embodiment, the different composition region 74 having a composition of which polarization can be easily inverted is provided in the ferroelectric film 34. Therefore, when the application direction of the external electric field is changed, the different composition region operates as the inversion domain core. Consequently, the growth of the inversion domain is promoted, and the ferroelectric capacitor characteristic of the semiconductor memory device can be improved. When the different composition region 74 is provided on the lower electrode 33, and when the composition of the different composition region 74 has a lattice constant near the lattice constant of the lower electrode 33, the different composition region 74 can operate as the inversion domain core, and the defect density near the interface between the ferroelectric film 34 and the lower electrode 33 can be decreased.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a field-effect transistor formed on a substrate;
an interlayer insulation film formed on the substrate on which the field-effect transistor is formed; and
a ferroelectric capacitor including a lower electrode connected via a plug to one of source/drain regions of the field-effect transistor, and formed on the interlayer insulation film, a ferroelectric film having a perovskite crystal structure used as a basic structure, and an upper electrode, wherein
a lattice matching region in which a lattice of the ferroelectric film is matched with a lattice of the lower electrode is formed in a range of a predetermined thickness of the ferroelectric film from the lower electrode.

2. The semiconductor memory device according to claim 1, wherein the lattice matching region is a different composition region which is made of a solid solution having same elements constituting the ferroelectric film and a different composition of the ferroelectric film.

3. The semiconductor memory device according to claim 2, wherein a mismatch between lattice constants of the different composition region and the lower electrode is equal to or smaller than 3%.

4. The semiconductor memory device according to claim 2, wherein the ferroelectric film has the different composition region having a composition formula of Pb(Zrₓ, Ti₁₋ₓ)O₃ where a composition rate x of Zr is smaller than 0.45, within a PZT film having a composition formula of Pb(Zrₓ, Ti₁₋ₓ)O₃ where the composition rate x of Zr is equal to or larger than 0.45.

5. The semiconductor memory device according to claim 1, wherein the lattice matching region is a defect suppressing region in which a metal element to suppress a defect generated at an interface between the ferroelectric film and the lower electrode is doped in the ferroelectric film.

6. The semiconductor memory device according to claim 5, wherein a mismatch between lattice constants of the defect suppressing region and the lower electrode is equal to or smaller than 3%.

7. The semiconductor memory device according to claim 5, wherein the ferroelectric film has a composition formula of Pb(Zrₓ, Ti₁₋ₓ) (PZT) having a perovskite structure, and
the defect suppressing region is formed by PZT having a part of Pb substituted by at least one of La and Nb.

8. The semiconductor memory device according to claim 7, wherein the lower electrode is made of a material having Ir doped with at least one type of element selected from a group of Ru, Pd, and Pt.

9. The semiconductor memory device according to claim 5, wherein the ferroelectric film has a composition formula of Pb(Zrₓ, Ti₁₋ₓ) (PZT) having a perovskite structure, and
the defect suppressing region is formed by PZT having a part of Zr and Ti substituted by Mn.

10. The semiconductor memory device according to claim 9, wherein the lower electrode is made of a material having Ir doped with at least one type of element selected from a group of Ru, Pd, and Pt.

11. The semiconductor memory device according to claim 5, wherein the ferroelectric film has a composition formula of Pb(Zrₓ, Ti₁₋ₓ) (PZT) having a perovskite structure, and
the defect suppressing region is formed by PZT having a part of Pb substituted by at least one type of element selected from a group of Ba, Sr, Ca, and La, and/or having a part of Zr and Ti substituted by at least one type of element selected from a group of Co, Ni, W, Fe, Hf, Sn, Zn, Ta, Mg, Mn, and Nb.

12. The semiconductor memory device according to claim 11, wherein the lower electrode is made of a material having Ir doped with at least one type of element selected from a group of Ru, Pd, and Pt.

13. The semiconductor memory device according to claim 5, wherein a thickness of the defect suppressing region is 5 to 20 nanometers.

14. A method of manufacturing a semiconductor memory device comprising:
forming a field-effect transistor on a substrate;
forming an interlayer insulation film covering the field-effect transistor on the substrate;
forming a contact hole connecting to source/drain regions of the field-effect transistor;
embedding a contact plug into the contact hole;
forming a lower electrode made of a conductive material on the interlayer insulation film on which the contact plug is formed;
forming a ferroelectric film including a lattice matching region to match a lattice of the ferroelectric film with a lattice of the lower electrode, on the lower electrode; and
forming an upper electrode on the ferroelectric film.

15. The method of manufacturing a semiconductor memory device according to claim 14, wherein
the ferroelectric film is formed by
forming, on the lower electrode, in a thickness equal to or smaller than 5 nanometers, a substitution element film containing a metal element capable of substituting a metal element constituting the ferroelectric film, and having an operation of suppressing the occurrence of a defect in the ferroelectric film,
forming the ferroelectric film on the substitution element film, and
diffusing the ferroelectric film and the substitution element film, by heat treatment, thereby forming the lattice matching region suppressing the occurrence of a defect at an interface between the ferroelectric film and the lower electrode, near the interface in the ferroelectric film.

16. The method of manufacturing a semiconductor memory device according to claim 15, wherein the ferroelectric film has a composition formula of Pb(Zrₓ, Ti₁₋ₓ) (PZT) having a perovskite structure, and
the substitution element film contains at least one type of metal element selected from a group of Ba, Sr, Ca, La, Co, Ni, W, Fe, Hf, Sn, Zn, Ta, Mg, Mn, and Nb.

17. The method of manufacturing a semiconductor memory device according to claim 14, wherein
the ferroelectric film is formed by
implanting, by ion implantation, a metal element capable of substituting a metal element constituting the ferroelectric film, and having an operation of suppressing the occurrence of a defect in the ferroelectric film, near the surface of the lower electrode, thereby forming a substitutable-element implantation region,
forming the ferroelectric film on the lower electrode on which the substitutable-element implantation region is formed, and
diffusing the ferroelectric film and the metal element within the substitutable-element implantation region, by heat treatment, thereby forming the lattice matching region suppressing the occurrence of a defect at an interface in the ferroelectric film between the ferroelectric film and the lower electrode, near the interface between the ferroelectric film and the lower electrode.

18. The method of manufacturing a semiconductor memory device according to claim 17, wherein the ferroelectric film has a composition formula of Pb(Zrₓ, Ti₁₋ₓ) (PZT) having a perovskite structure, and
the element implanted by the ion implantation contains at least one type of metal element selected from a group of Ba, Sr, Ca, La, Co, Ni, W, Fe, Hf, Sn, Zn, Ta, Mg, Mn, and Nb.

19. The method of manufacturing a semiconductor memory device according to claim 14, wherein
the ferroelectric film is formed by
forming a lower ferroelectric film becoming the lattice matching region, on the lower electrode, and
forming on the lower ferroelectric film, an upper ferroelectric film which is made of a solid solution having the same element constituting the lower ferroelectric film and a different composition of the lower ferroelectric film.

20. The method of manufacturing a semiconductor memory device according to claim 19, wherein the ferroelectric film is a PZT film having a composition formula of Pb(Zrₓ, Ti₁₋ₓ)O₃,
the PZT film is formed so that a composition rate x of Zr becomes smaller than 0.45, for the lower ferroelectric film, and
the PZT film is formed so that the composition rate x of Zr becomes equal to or larger than 0.45, for the upper ferroelectric film.
